(19) United States
(12) Patent Application Publication
(10) Pub. No.: US 2025/0157961 A1
(43) Pub. Date: May 15, 2025

(54) SEMICONDUCTOR DEVICE

(71) Applicant: DENSO CORPORATION, Kariya-city (JP)

(72) Inventors: Shiro MIWA, Kariya-city (JP); Kazuyuki KAKUTA, Kariya-city (JP); Tsuyoshi FUJIWARA, Kariya-city (JP)

(21) Appl. No.: 19/022,203

(22) Filed: Jan. 15, 2025

Related U.S. Application Data
(63) Continuation of application No. PCT/JP2023/023837, filed on Jun. 27, 2023.

(30) Foreign Application Priority Data
Jul. 25, 2022 (JP) 2022-117887

(51) Int. Cl. H01L 23/00; H01L 23/29; H01L 23/31; H01L 23/495

(52) U.S. Cl. CPC H01L 24/05; H01L 23/293; H01L 23/3171; H01L 24/06; H01L 24/40; H01L 24/48; H01L 24/73; H01L 23/495; H01L 2224/04034; H01L 2224/04042; H01L 2224/05155; H01L 2224/05567; H01L 2224/05655; H01L 2224/0603; H01L 2224/06051; H01L 2224/40245; H01L 2224/48245; H01L 2224/73221

(57) ABSTRACT

A semiconductor device includes: a semiconductor substrate for a semiconductor element; a first electrode and a second electrode provided on one surface of the semiconductor element; and a partition wall provided on the one surface of the semiconductor element to separate the first electrode from the second electrode. The first electrode and the second electrode are formed of an Ni plating layer, and the phosphorus concentration in the Ni plating layer is 4 wt % or less. The partition wall is made of an insulating material and has a shape protruding toward the first electrode or the second electrode.

### CROSS REFERENCE TO RELATED APPLICATIONS

The present application is a continuation application of International Patent Application No. PCT/JP2023/023837 filed on Jun. 27, 2023, which designated the U.S. and claims the benefit of priority from Japanese Patent Application No. 2022-117887, filed on Jul. 25, 2022. The entire disclosures of all of the above applications are incorporated herein by reference.

### TECHNICAL FIELD

The present disclosure relates to a semiconductor device.

### BACKGROUND

A semiconductor device is mountable on a printed circuit board. The semiconductor device includes a semiconductor element, a lead frame, a clip, and a sealing resin portion.

### SUMMARY

According to one aspect of the present disclosure, a semiconductor device includes: a semiconductor substrate for a semiconductor element; a first electrode provided on one surface of the semiconductor element and formed of an Ni plating layer; a second electrode provided on the one surface of the semiconductor element and formed of the Ni plating layer; and a partition wall formed of an insulating material and provided on the one surface of the semiconductor element to separate the first electrode and the second electrode. A phosphorus concentration in the Ni plating layer of the first electrode and the second electrode is 4 wt % or less. The partition wall has a shape protruding toward the first electrode or the second electrode.

### BRIEF DESCRIPTION OF DRAWINGS

FIG. 1 is a cross-sectional view showing a schematic configuration of a semiconductor device according to an embodiment.

FIG. 2 is a schematic plan view showing the semiconductor device.

FIG. 3 is an enlarged cross-sectional view showing a semiconductor element of the semiconductor device.

FIG. 4 is a schematic plan view showing an Ni plating layer and a passivation film in the semiconductor element of FIG. 3.

FIG. 5 is a graph showing results of computer simulations regarding a stress state when Si substrates of various thicknesses are used as the semiconductor substrate shown in FIG. 3.

FIG. 6 is a graph showing results of computer simulations regarding a stress state when SiC substrates of various thicknesses are used as the semiconductor substrate shown in FIG. 3.

FIG. 7 is a graph showing a relationship between a ratio of columnar crystal layer and a crack occurrence rate in the Ni plating layer shown in FIG. 3.

FIG. 8 is a graph showing a relationship among a ratio of columnar crystal layer in the Ni plating layer, a thickness of a semiconductor substrate shown in FIG. 3, and a state of crack occurrence.

FIG. 9 is a graph showing a relationship among a ratio of columnar crystal layer in the Ni plating layer, a thickness of a semiconductor substrate shown in FIG. 3, and a state of crack occurrence.

FIG. 10 is a schematic plan view showing an Ni plating layer and a passivation film in a modification of the semiconductor element shown in FIG. 3.

FIG. 11 is a schematic plan view showing an Ni plating layer and a passivation film in another modification of the semiconductor element shown in FIG. 3.

FIG. 12 is a schematic enlarged cross-sectional view showing a modification of the semiconductor element shown in FIG. 3.

### DETAILED DESCRIPTION

A semiconductor device is mountable on a printed circuit board. The semiconductor device includes a semiconductor element, a lead frame, a clip, and a sealing resin portion. The semiconductor element is, for example, a Metal-Oxide-Semiconductor Field-Effect Transistor (MOSFET) or an Insulated-Gate Bipolar Transistor (IGBT). A structure including the semiconductor device and the printed circuit board on which the semiconductor device is mounted is called an electronic device.

The semiconductor element has electrodes on both sides. Specifically, a drain electrode is provided on the back side of the semiconductor element. A source electrode and a gate electrode are provided on the front side of the semiconductor element. The lead frame has a drain terminal and a source terminal. The drain terminal has a semiconductor element mounted on the mounting surface. That is, the drain terminal is electrically connected to the drain electrode via a conductive connecting member such as solder. The source terminal is electrically connected to the source electrode via a clip. Specifically, the clip is mainly made of a conductive material such as a metal material. The clip has an electrode facing portion facing the source electrode, a terminal facing portion facing the source terminal, and a connecting portion connecting the electrode facing portion and the terminal facing portion. The electrode facing portion, the terminal facing portion, and the connecting portion are configured as an integral part. The electrode facing portion of the clip is electrically connected to the source electrode via solder. The terminal facing portion of the clip is electrically connected to the source terminal via solder.

For example, a module including a semiconductor element (e.g., a power module) and a circuit are integrally mounted on a printed circuit board, in order to reduce the area of a semiconductor device or electronic device. Here, it is preferable that the current-carrying electrode such as drain terminal and source terminal in a semiconductor element has as large an area as possible. In order to eliminate parasitic resistance and achieve low on-resistance by adopting so-called clip mounting, it is preferable to use solder in the semiconductor device that has a higher melting point than the solder used when mounting on a printed circuit board, so as to increase the area of the current-carrying electrode. If a control electrode such as gate electrode is formed on the same surface as the current-carrying electrode, there is a concern that the element area will become large. The present disclosure has been made in view of the circumstances and the like exemplified above. The present disclosure provides, for example, a technique that can effectively realize a reduction in the area of a semiconductor device.

According to one aspect of the present disclosure, a semiconductor device includes: a semiconductor substrate constituting a semiconductor element; a first electrode provided on one surface of the semiconductor element and formed of an Ni plating layer; a second electrode provided on the one surface of the semiconductor element and formed of an Ni plating layer; and a partition wall formed of an insulating material and provided on the one surface of the semiconductor element so as to separate the first electrode and the second electrode. A phosphorus concentration in the Ni plating layer of the first electrode and the second electrode is 4 wt % or less. The partition wall has a convex shape protruding toward the first electrode or the second electrode.

### First Embodiment

Embodiments of the present disclosure will be described below with reference to the drawings. Note that the descriptions of each drawing and the corresponding device configurations and their functions or operations described below have been simplified to concisely explain the contents of this disclosure and are not intended to limit the contents of this disclosure in any way. Therefore, it goes without saying that the exemplary configurations shown in the drawings do not necessarily match the specific configurations that are actually manufactured and sold. In other words, unless the applicant explicitly limits it through the prosecution history of this application, it goes without saying that this disclosure should not be interpreted in a limited manner by the descriptions in each drawing or the corresponding descriptions of the device configuration and its functions or operations described below.

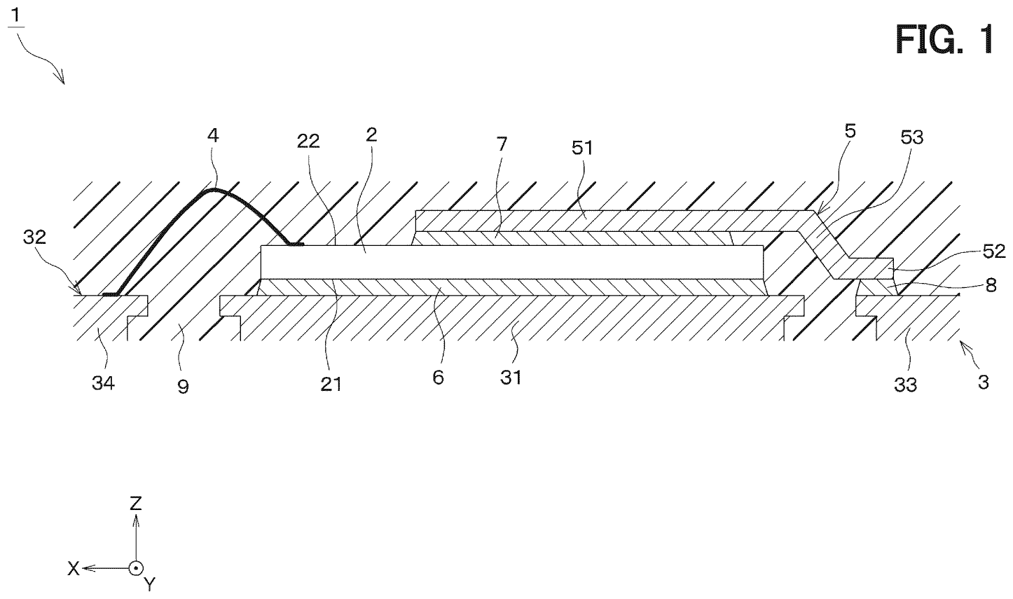

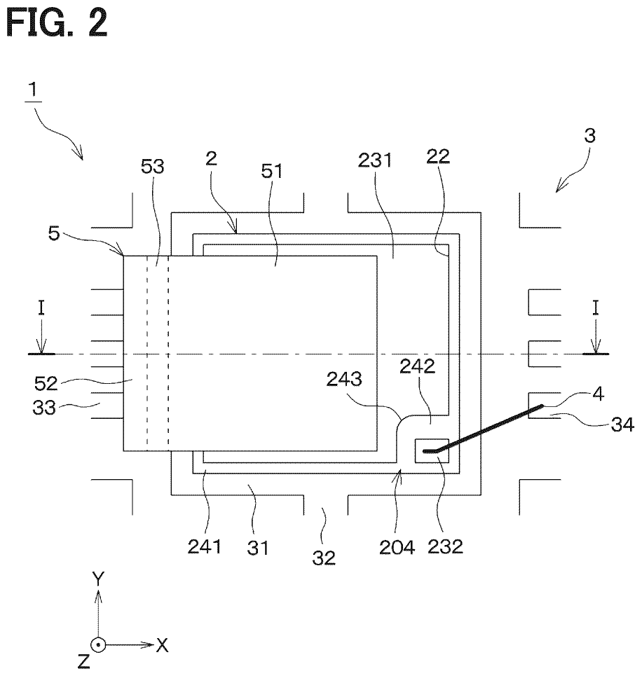

A schematic configuration of a semiconductor device 1 according to the present embodiment will be described with reference to FIGS. 1 and 2. FIG. 1 corresponds to a cross-sectional view taken along line I-I in FIG. 2. For ease of explanation, a right-handed XYZ orthogonal coordinate system is set so that the Z direction is parallel to the thickness direction of the semiconductor device 1. That is, in the following description, the thickness direction refers to the Z direction in the drawings. Moreover, any direction perpendicular to the thickness direction is referred to as an in-plane direction, which is parallel to the XY plane in the drawing. Furthermore, viewing the semiconductor device 1 and its components from the upper side in the Z direction in FIG. 1 is referred to as a plan view. That is, the shape of a certain component in a plan view corresponds to the shape of the same component projected onto the XY plane in the drawing. The shape in a plan view, that is, the shape in an in-plane direction, is referred to as an in-plane shape.

The semiconductor device 1 is mounted on a printed circuit board (not shown) by soldering to form an electronic device. As shown in FIG. 1, the semiconductor device 1 includes a semiconductor element 2, a lead frame 3, a bonding wire 4, a clip 5, a first solder layer 6, a second solder layer 7, a third solder layer 8, and a molding resin 9. The semiconductor element 2, the lead frame 3, the bonding wire 4, the clip 5, the first solder layer 6, the second solder layer 7, and the third solder layer 8 are covered and sealed with the molding resin 9 made of an electrically insulating synthetic resin such as epoxy resin. The configuration of the semiconductor device 1 according to this embodiment will be described in detail below.

In this embodiment, the semiconductor device 1 is a so-called power device, that includes the semiconductor element 2 such as a MOSFET, which is a power semiconductor. As shown in FIG. 2, the semiconductor element 2 is formed in a substantially rectangular shape in a plan view. A bottom surface 21 of the semiconductor element 2 perpendicular to the thickness direction is joined to an element mounting portion 31 of the lead frame 3 via the first solder layer 6 having a melting point of 290° C. or higher. That is, the semiconductor element 2 is electrically connected to the element mounting portion 31 of the lead frame 3 via the first solder layer 6. The upper surface 22 of the semiconductor element 2 perpendicular to the thickness direction is joined to the clip 5 via the second solder layer 7 having a melting point of 290° C. or higher. That is, the semiconductor element 2 is electrically connected to the clip 5 via the second solder layer 7.

The lead frame 3 is formed of a metal plate conductor such as copper. The lead frame 3 has lead portions 32 in addition to the element mounting portion 31. The lead portions 32 are provided around the element mounting portion 31, which is also called a die pad. Of the lead portions 32, a source terminal portion 33 is joined to the clip 5 via the third solder layer 8 having a melting point of 290° C. or higher. That is, the source terminal portion 33 is electrically connected to the clip 5 via the third solder layer 8. A gate terminal portion 34 of the lead portions 32 is electrically connected to a control electrode 232 (described later) provided on the upper surface 22 of the semiconductor element 2 via the bonding wire 4.

The clip 5 is formed seamlessly and integrally from a highly conductive metal plate such as copper. The clip 5 has an element facing portion 51, a lead frame facing portion 52, and a connecting portion 53. Each of the element facing portion 51, the lead frame facing portion 52, and the connecting portion 53 is formed in a flat plate shape. The element facing portion 51 is joined to the second solder layer 7. The lead frame facing portion 52 is joined to the third solder layer 8. The element facing portion 51 and the lead frame facing portion 52 are provided in parallel to each other. The lead frame facing portion 52 is provided at a position offset from the element facing portion 51 in the thickness direction, that is, downward (toward the negative side) in the Z direction in FIG. 1. The connecting portion 53 is provided between the element facing portion 51 and the lead frame facing portion 52. That is, the clip 5 is formed by bending at the boundary between the element facing portion 51 and the connecting portion 53 and at the boundary between the lead frame facing portion 52 and the connecting portion 53.

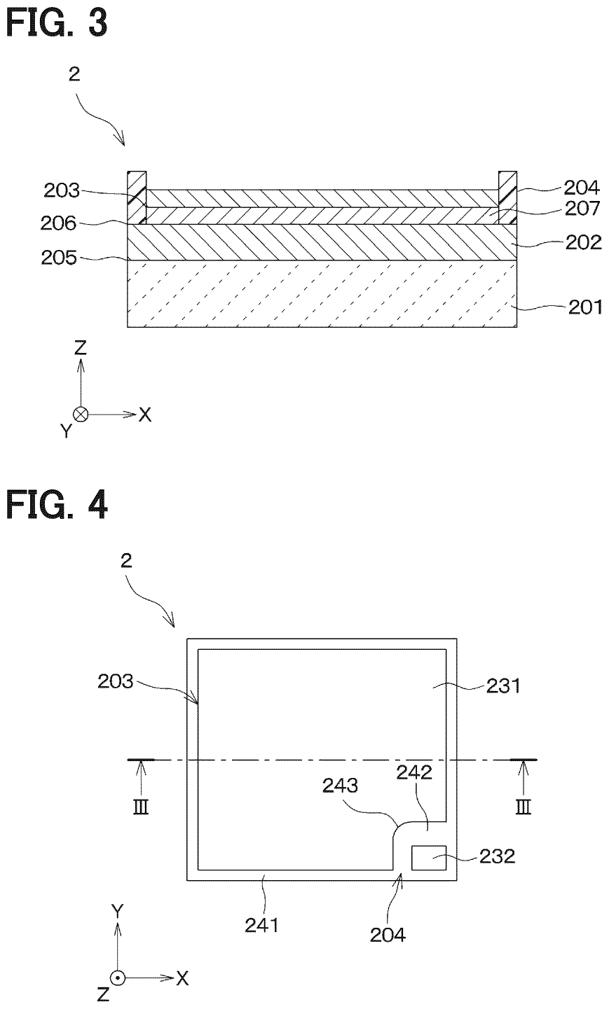

As the overall configuration, the semiconductor device 1 has the lead frame 3 and the clip 5. Further detailed explanation of the lead frame 3 and the clip 5 will be omitted. Hereinafter, the semiconductor device 1 will be described with reference to FIGS. 3 and 4 in addition to FIGS. 1 and 2. FIG. 3 is a cross-sectional view taken along line III-III in FIG. 4.

As shown in FIG. 3, the semiconductor element 2 includes a semiconductor substrate 201, a base metal layer 202, an Ni plating layer 203, and a passivation film 204. The semiconductor substrate 201 is a thin plate member made of a silicon-based semiconductor material such as Si, SiC, or SiN, and has circuit elements (not shown in FIG. 3) such as MOSFETs formed thereon. The base metal layer 202 is provided on the semiconductor substrate 201 and is made of aluminum or an aluminum alloy. The aluminum alloy constituting the base metal layer 202 may be, for example, AlSi, AlCu, AlSiCu, or the like. The Ni plating layer 203 and the passivation film 204 are provided on the base metal layer 202. The Ni plating layer 203 is a low phosphorus Ni plating film with a phosphorus concentration of 4% or less by weight, and is formed in a substantially rectangular shape, in a plan view, that is slightly smaller than the in-plane shape of the semiconductor element 2. That is, the passivation film 204 is provided around the Ni plating layer 203. The passivation film 204 is made of an insulating material such as polyimide resin. A first interlayer interface 205, which is a bonding interface between the semiconductor substrate 201 and the base metal layer 202, is formed flat along the in-plane direction. A second interlayer interface 206, which is a bonding interface between the base metal layer 202 and the Ni plating layer 203 and between the base metal layer 202 and the passivation film 204, is formed flat along the in-plane direction.

As shown in FIG. 3, the Ni plating layer 203 has a columnar crystal layer 207. The columnar crystal layer 207 formed in the initial stage of deposition of the Ni plating layer 203 is provided on the lower side in the Ni plating layer 203, that is, on the second interlayer interface 206. In this embodiment, the Ni plating layer 203 is formed so that the ratio of the thickness of the columnar crystal layer 207 to the total thickness of the Ni plating layer 203 is 50% or less.

As shown in FIG. 2, the current-carrying electrode 231 and the control electrode 232 are provided on the upper surface 22 of the semiconductor element 2. The current-carrying electrode 231 and the control electrode 232 are formed of the Ni plating layer 203. In this embodiment, the current-carrying electrode 231 corresponding to a first electrode and the control electrode 232 corresponding to a second electrode are arranged in the in-plane direction. Specifically, as shown in FIG. 4, the control electrode 232 is provided at one corner of the approximately rectangular in-plane shape of the Ni plating layer 203, that is, in the lower right corner in FIG. 4, and has a relatively small area. In contrast, the current-carrying electrode 231 has larger area than the control electrode 232 so as to occupy most of the approximately rectangular in-plane shape of the Ni plating layer 203, other than the control electrode 232.

The passivation film 204 has a side wall 241 and a partition wall 242. The side wall 241 is provided to surround the periphery, i.e., the outer side, of the current-carrying electrode 231 and the control electrode 232. The partition wall 242 is provided between the current-carrying electrode 231 and the control electrode 232 so as to separate the current-carrying electrode 231 and the control electrode 232. In this embodiment, the partition wall 242 has a convex shape protruding toward the current-carrying electrode 231. That is, the partition wall 242 is formed in a substantially L-shape, in a plan view, that opens toward the control electrode 232. In this manner, the current-carrying electrode 231, the control electrode 232, and the partition wall 242 are disposed inside the side wall 241 formed in a substantially rectangular ring shape. The side wall 241 and the partition wall 242 are formed in a wall shape standing approximately vertically from the second interlayer interface 206 upward (along the positive side) in the Z direction. That is, the inner and outer wall surfaces of the side wall 241 and the partition wall 242 along the thickness direction are provided approximately parallel to the YZ plane. The side wall 241 and the partition wall 242 are formed seamlessly and integrally from the same material.

The partition wall 242 has a protrusion 243. The protrusion 243 is a corner of the partition wall 242 that is closest to the center position of the current-carrying electrode 231 in the in-plane direction, and is provided so as to protrude toward the center of the current-carrying electrode 231 in the in-plane direction. The protrusion 243 is formed in a rounded shape, specifically, in a plan view. Specifically, in this embodiment, the protrusion 243 is formed so that the radius of curvature of the round shape is 30 μm or more.

Hereinafter, the effects achieved by the configuration of this embodiment will be described with reference to the drawings.

In a comparison example, a circuit and a semiconductor module are integrally mounted on a printed circuit board to reduce the cost and the area in an electronic device. It is preferable that an electrode for current flow, such as the drain terminal and the source terminal, is formed with as large an area as possible in order to pass a comparatively large current therethrough. In addition, by adopting clip mounting, parasitic resistance is eliminated, achieving low on-resistance. In order to realize such a configuration, it is preferable to use a solder in the semiconductor device 1 that has a higher melting point than the solder used when mounting the semiconductor device on the printed circuit board, so as to increase the source area. When the melting point of such high melting point solder is, for example, 290° C. or higher, a processing temperature of about 390° C. is required in the mounting process. The semiconductor element 2 as the semiconductor module is plated with Ni for solder bonding. In this regard, cracks may occur in the Ni plating due to thermal stress during reflow of high melting point solder, using a medium-phosphorus Ni plating.

Further, as in a comparison example, a current-carrying electrode such as a source electrode and a control electrode such as a gate electrode may be provided on the same surface. In such a configuration, in order to reduce the area of the elements while making the area of the current-carrying electrode as large as possible, it is preferable to form the control electrode with a small area at one corner of a single rectangle within which the two electrodes are arranged in a plan view. In this case, from the viewpoint of insulation and electrode protection, it is preferable to provide a wall having a convex shape to separate the two electrodes. However, cracks are likely to occur in the Ni plating due to stress concentration caused by, for example, the convex shape of the wall.

In this regard, the inventors have focused on the following facts. As is clear from the NI-P binary system diagram, in so-called low-phosphorus Ni plating, in which the phosphorus concentration is 4 wt % or less, the phase transition temperature at which the film stress changes is high. As shown in FIG. 3, in the initial stage of the deposition of the Ni plating layer 203, the columnar crystal layer 207 is formed. The columnar crystal layer 207 becomes defects in the film. Therefore, in this embodiment, as shown in FIGS. 3 and 4, the ratio of the thickness of the columnar crystal layer 207 to the thickness of the Ni plating layer 203 is set to 50% or less. Furthermore, the protrusion 243 of the partition wall 242 that protrudes toward the current-carrying electrode 231 is formed in a rounded shape, in a plan view, while separating the current-carrying electrode 231 from the control electrode 232. Specifically, the protrusion 243 is formed into a round shape in a plan view. This makes it possible to effectively restrict cracks from occurring in the Ni plating layer 203 provided on the semiconductor element 2.

The preferred value of the planar shape, i.e., the radius of curvature, of the protrusion 243 can be determined taking into consideration the variety of chip sizes and other factors, as well as variations during manufacturing. Specifically, for example, the thickness of the semiconductor substrate 201 may be about 70 μm or less, or may be within a range more than 70 μm and less than 160 μm. The following will consider the specifications of the semiconductor element 2, such as the material and the thickness of the semiconductor substrate 201, and the radius of curvature of the protrusion 243 of the partition wall 242.

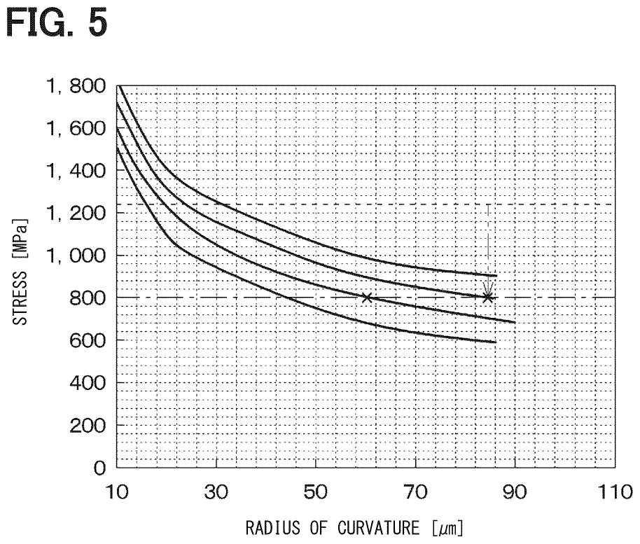

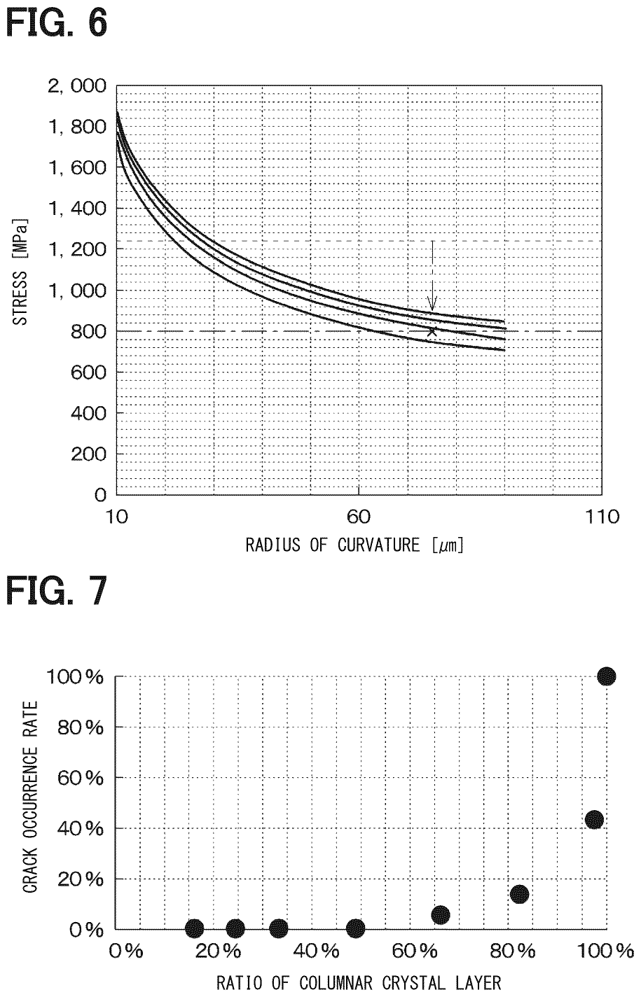

FIG. 5 shows a relationship between the radius of curvature of the protrusion 243, and the stress acting on the Ni plating layer 203, depending on the substrate thickness, when a Si substrate is used as the semiconductor substrate 201. FIG. 6 shows a relationship between the radius of curvature of the protrusion 243, and the stress acting on the Ni plating layer 203, depending on the substrate thickness, when a SiC substrate is used as the semiconductor substrate 201. The curves in FIGS. 5 and 6, from the bottom, represent the substrate thicknesses of 50 μm, 70 μm, 140 μm, and 725 μm. The plating thickness, that is, the film thickness of the Ni plating layer 203 is set to 3 μm. The horizontal dashed line in FIGS. 5 and 6 indicates the calculated stress of 1259 MPa when a crack occurs in case where the substrate thickness is 80 μm, the plating thickness is 4 μm, the radius of curvature is 22 μm, and the reflow temperature is 390° C. As shown in FIGS. 5 and 6, the larger the radius of curvature, the smaller the stress and the less likely cracks will occur. Specifically, for example, when the radius of curvature is changed from 20 μm to 60 μm, the generated stress becomes approximately 0.67 times. Furthermore, for the same radius of curvature, the smaller the substrate thickness, the smaller the stress and the less likely cracks will occur. Specifically, for example, when the substrate thickness is changed from 70 μm to 140 μm, the generated stress increases by about 1.1 times. In addition, under conditions below the dashed line in FIGS. 5 and 6, the generated stress is smaller than that when cracks occur.

However, various variations due to processing tolerances and the like may occur during the actual manufacturing of products. For this reason, it is necessary to provide a margin that takes such variations into consideration. Specifically, for example, if the radius of curvature is 30 μm or more for a substrate thickness of 70 μm, and if the radius of curvature is 60 μm or more for a substrate thickness of 140 μm, it is possible to provide a sufficient margin taking into consideration variations. In both the cases of SiC substrate and Si substrate, when the radius of curvature is 60 μm or more, the maximum stress is less than 1000 MPa regardless of the substrate thickness, therefore does not exceed the fracture stress. Furthermore, in order to obtain an even larger margin, for example, if a substrate thickness of 70 μm is considered, the variation in generated stress relative to the variations in substrate thickness, plating thickness, and radius of curvature is approximately ±5%. Stable production is possible, even if a variation of 10% is taken into consideration in the development of product types such as changes in chip size, the radius of curvature that does not exceed 1259 MPa is approximately 60 μm. See the X mark, in FIGS. 5 and 6, at the intersection with the horizontal dashed line. Similarly, when the substrate thickness is 140 μm, the radius of curvature that does not exceed 1259 MPa is approximately 85 μm. In contrast, in the case of medium-phosphorus Ni plating, a radius of curvature of 94 μm or more is required relative to a substrate thickness of 122 μm and a reflow temperature of 290° C. Similarly, in the case of SiC substrate, not to exceed 1259 MPa, the radius of curvature is approximately 75 μm relative to a substrate thickness is 70 μm.

FIG. 7 shows the results of evaluating the crack occurrence rate, by changing the ratio of the columnar crystal layer, when a Si substrate having a thickness of 70 μm is used as the semiconductor substrate 201 and the radius of curvature is set to 20 μm. The ratio of columnar crystal layer is a ratio of the maximum thickness of the columnar crystal layer 207 to the layer thickness of the Ni plating layer 203. The “maximum thickness” is the maximum value when the thickness is measured at multiple points in the in-plane direction. As shown in FIG. 7, by setting the ratio of the columnar crystal layer to 50% or less, the occurrence of cracks can be effectively suppressed.

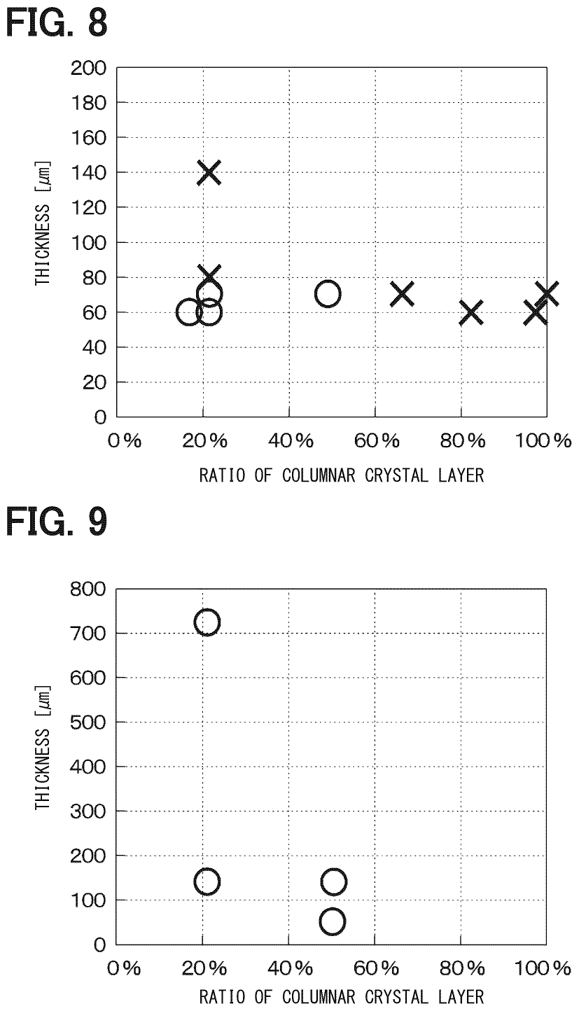

FIG. 8 shows the results of evaluating the state of crack occurrence, by changing the substrate thickness and the ratio of the columnar crystal layer, when a Si substrate is used as the semiconductor substrate 201 and the radius of curvature is set to 20 μm. In FIG. 8, the plots marked with circle indicate that no cracks occurred, and the plots marked with X indicate that cracks occurred. As shown in FIG. 8, by setting the substrate thickness to 70 μm or less and the ratio of the columnar crystal layer to 50% or less, the occurrence of cracks can be effectively suppressed.

FIG. 9 shows the results of evaluating the state of crack occurrence, by changing the substrate thickness and the ratio of the columnar crystal layer, when a Si substrate is used as the semiconductor substrate 201 and the radius of curvature is set to 60 μm. As shown in FIG. 9, by setting the substrate thickness to 725 μm or less and the ratio of columnar crystal layer to 50% or less, the occurrence of cracks can be effectively suppressed.

Considering the above-mentioned results comprehensively, when the semiconductor element 2 is formed of the semiconductor substrate 201 having a thickness of 70 μm or less, for example, 70 to 50 μm or 70 to 25 μm, it is preferable that the ratio of columnar crystal layer is 50% or less and the radius of curvature is 30 μm or more. When the semiconductor element 2 is formed of the semiconductor substrate 201 having a thickness of 160 μm or less, for example, 160 to 100 μm or 160 to 75 μm, it is preferable that the ratio of columnar crystal layer is 50% or less and the radius of curvature is 60 μm or more. As a result, the occurrence of cracks in the Ni plating layer 203 can be effectively suppressed up to a higher temperature range, i.e., up to 390° C. Furthermore, even if the radius of curvature is reduced in the comparative temperature range, i.e., 290° C., the occurrence of cracks in the Ni plating layer 203 can be effectively suppressed. The ratio of the columnar crystal layer can be set to 50% or less by appropriately adjusting the plating conditions. The crystalline state in electroless Ni plating can be changed by a complexing agent, a trace amount of additives, and the like, see, for example, the following reference material: Kamei, Masaru et al., “Influence of Kinds of Copper foil, Crystal Structure and Thickness of Electroless Ni—P on the Bend Durability of Copper Wiring” MES2016 (26th Microelectronics Symposium) Abstract Collection, September 2016, pp. 63-66, which is incorporated herein by reference. The plating conditions can be satisfactorily set without excessive trial and error, by simple and small number of trials using, for example, an L8 orthogonal table or an L12 orthogonal table in an experimental design method.

It is also preferable that the step at the first interlayer interface 205 and the second interlayer interface 206 be small at least at the position corresponding to the partition wall 242, i.e., the protrusion 243, in the in-plane direction. This effectively restricts cracks from occurring due to stress concentration. Specifically, for example, it is preferable that the first interlayer interface 205 is flattened so that the step is 0.2 μm or less. Alternatively, for example, it is preferable that the second interlayer interface 206 is flattened so that the step is equal to or smaller than a dimension corresponding to 10% of the film thickness of the base metal layer 202. Such planarization can be achieved by using, for example, BPSG reflow technology, chemical mechanical polishing, aluminum reflow technology, or the like. BPSG is an abbreviation for Boron Phosphorus Silicon Glass.

### Second Embodiment

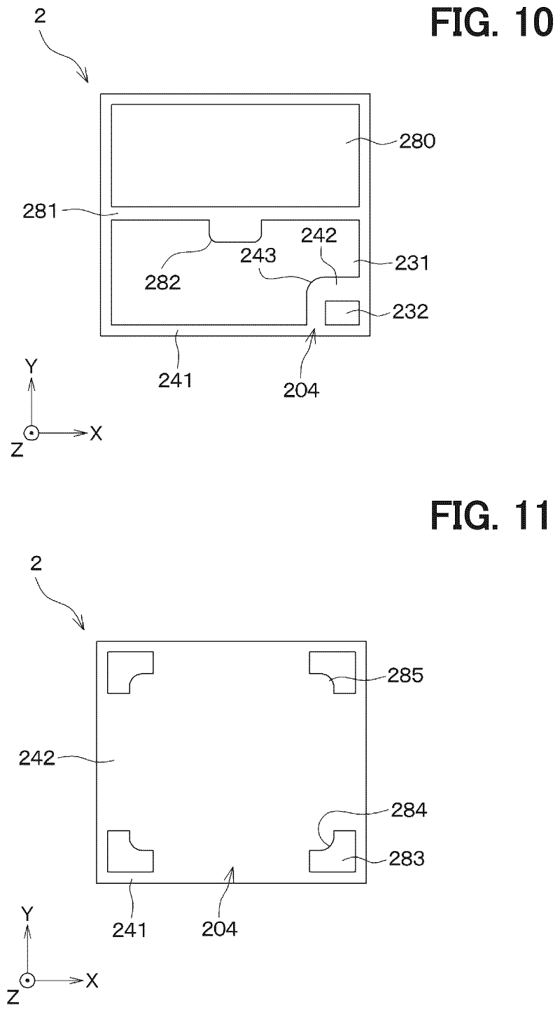

A second embodiment will be described with reference to FIG. 10. In the following description of the second embodiment, portions different from those of the first embodiment will be mainly described. In the first embodiment and the second embodiment, portions that are the same or equivalent to each other are assigned the same reference numerals. Therefore, in the following description of the second embodiment, the description of the first embodiment may be appropriately incorporated for the components having the same reference numerals as those of the first embodiment, unless there is a technical contradiction or a special additional description. The same applies to the other embodiments described below.

As shown in FIG. 10, the semiconductor element 2 has an additional electrode 280 in addition to the current-carrying electrode 231 and the control electrode 232. The passivation film 204, which is seamlessly formed from an insulating material such as polyimide resin, has an additional partition wall 281 in addition to the side wall 241 and the partition wall 242. The current-carrying electrode 231 and the additional electrode 280 are separated by the additional partition wall 281. That is, in this embodiment, the current-carrying electrode 231 in the first embodiment is divided into two by the additional partition wall 281. In this embodiment, the additional partition wall 281 is provided along the X direction in FIG. 10. The additional partition wall 281 has a protrusion 282. The protrusion 282 protrudes toward the current-carrying electrode 231 in a plan view, that is, to the negative side in the Y direction. For example, a temperature sensor or the like may be provided at a position corresponding to the protrusion 282 in a plan view. The corners of the protrusion 282 are formed into a round shape having a predetermined radius of curvature in a plan view. According to this configuration, the occurrence of cracks in the current-carrying electrode 231 at the locations where the partition wall 242 and the protrusion 282 are provided can be effectively suppressed.

### Third Embodiment

A third embodiment will be described with reference to FIG. 11. In this embodiment, plural terminal electrodes 283 are provided at the corners of the semiconductor element 2 in the in-plane direction. The terminal electrode 283 is formed of the Ni plating layer 203, similar to the current-carrying electrode 231 in the first embodiment. The terminal electrode 283 is formed in a substantially rectangular shape in a plan view with recesses 284 provided at the corners thereof. The recess 284 is open toward the center of the semiconductor element 2. The recess 284 is formed in a round shape having a predetermined radius of curvature in a plan view.

A partition wall 242 having a substantially cross shape in a plan view is provided between the terminal electrodes 283. The partition wall 242 has a protrusion 285. The protrusion 285 is disposed at a position corresponding to the recess 284 in the terminal electrode 283. Moreover, the protrusion 285 is provided so as to fit closely with the recess 284 without any gaps in the plan view. That is, the protrusion 285 is formed in a round shape having a predetermined radius of curvature corresponding to the radius of curvature of the recess 284 in a plan view. According to this configuration, the occurrence of cracks in the terminal electrode 283 at the location where the recess 284 is provided can be effectively suppressed.

### Fourth Embodiment

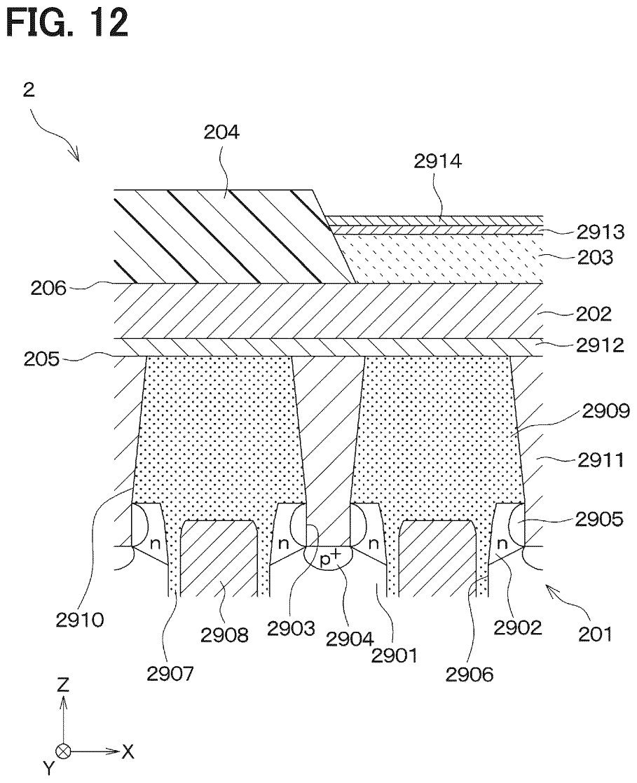

A fourth embodiment will be described with reference to FIG. 12. In this embodiment, the semiconductor substrate 201 is modified to have a so-called trench gate structure, as shown in FIG. 12, in which JP 2022-7762 A is incorporated by reference.

Specifically, referring to FIG. 12, a source layer 2902 is formed on a surface portion of a channel layer 2901. A contact trench 2903 is formed in the semiconductor substrate 201 so as to penetrate the source layer 2902 and reach the channel layer 2901. Therefore, the channel layer 2901 is exposed at the bottom surface of the contact trench 2903. A part of the channel layer 2901 exposed from the contact trench 2903 has a first contact region 2904 which is a p+ type channel layer contact region serving as a contact. A part of the source layer 2902 exposed from the side surface of the contact trench 2903 has a second contact region 2905 which is an n+ type source layer contact region serving as a contact.

The semiconductor substrate 201 has plural trenches 2906 between the channel layer 2901 and the source layer 2902. The trenches 2906 are formed in a stripe shape at equal intervals along the Y direction which is one of the in-plane direction on one surface of the semiconductor substrate 201, in FIG. 12. The trench 2906 is provided so as to penetrate the channel layer 2901 in the thickness direction and reach a drift layer (not shown). Each of the trenches 2906 is embedded with a gate insulation film 2907 and a gate element 2908. The gate insulation film 2907 covers a wall surface of each of the trenches 2906. The gate element 2908 is formed of polysilicon or the like and is formed on the gate insulation film 2907. As a result, a trench gate structure is formed.

An interlayer insulating film 2909 is formed on one surface of the semiconductor substrate 201 adjacent to the channel layer 2901. The interlayer insulating film 2909 has a contact hole 2910 communicating with the contact trench 2903. An embedded portion 2911 is disposed in the contact hole 2910 and the contact trench 2903 and connected to the first contact region 2904 and the second contact region 2905. The embedded portion 2911 is made of, for example, a tungsten plug.

A barrier metal layer 2912 is provided between the embedded portion 2911 and the base metal layer 202. The barrier metal layer 2912 is formed by stacking, for example, titanium nitride and titanium. The first interlayer interface 205 is formed by the lower surface of the barrier metal layer 2912. The second interlayer interface 206 is formed by the upper surface of the base metal layer 202. A Pd layer 2913 and an Au layer 2914 are arranged in this order on the Ni plating layer 203.

In such a configuration, as in the first embodiment, it is preferable to reduce the step at the first interlayer interface 205 and the second interlayer interface 206 at least at positions corresponding to the partition wall 242 (i.e., the protrusion 243 and the protrusion 285) and the additional partition wall 281 (i.e., the protrusion 282). Specifically, for example, it is preferable that the step at the first interlayer interface 205 is equal to or smaller than the dimension corresponding to the film thickness of the barrier metal layer 2912, that is, 0.2 μm or smaller. This effectively restricts cracks from occurring in the Ni plating layer 203 due to stress concentration.

### Modifications

The present disclosure is not necessarily limited to the above embodiments. Thus, it is possible to appropriately modify the above-described embodiments. Hereinafter, typical modifications will be described. In the following description of the modifications, differences from the above embodiments will be mainly described. In the above embodiments and the modifications, the same reference numerals are assigned to the same or equivalent parts. Therefore, in the description of the following modifications, regarding components having the same reference numerals as the components of the above-described embodiment, the description in the above-described embodiment can be appropriately cited unless there is a technical inconsistency or a specific additional explanation.

The present disclosure is not limited to the specific device configurations described in the above embodiments. That is, as described above, the description of the above embodiment has been simplified in order to concisely explain the contents of the present disclosure. For this reason, illustrations and descriptions of components that are normally provided in products that are actually manufactured and sold, such as casings, bonding materials, terminals, wiring, etc., are appropriately omitted in the above embodiments and the corresponding drawings.

The present disclosure is suitably applicable to the semiconductor device 1 in various package types such as SOP, QFP, SON, and QFN. SOP is an abbreviation for Small Outline Package. QFP is an abbreviation for Quad Flat Package. SON is an abbreviation for Small Outline Non-Leaded Package. QFN is an abbreviation for Quad Flat Non-Leaded Package.

The semiconductor element 2 may have a configuration as an IGBT or an RC-IGBT in which an IGBT and a diode are integrated together. RC is an abbreviation for Reverse Conducting.

As shown in FIG. 12, the wall surface of the passivation film 204 along the thickness direction may be provided as an inclined surface inclined with respect to the Z direction in FIG. 12.

The additional partition wall 281 may be provided to extend along the Y direction in FIG. 10. The protrusion 282 may be provided so as to protrude toward the additional electrode 280 in a plan view. Alternatively, the protrusion 282 may be provided so as to protrude toward the current-carrying electrode 231 and the additional electrode 280 in a plan view.

In the above description, plural elements formed integrally with each other with no seam may be formed by bonding separate members together. Similarly, plural elements formed by bonding separate members together may be formed integrally with each other with no seam. In the above description, plural elements formed of the same material may be formed of different materials. Similarly, plural elements formed of different materials may be formed of the same material.

The constituent element(s) of each of the above embodiments and the above modifications is/are not necessarily essential unless it is specifically stated that the constituent element(s) is/are essential in the above embodiments, or unless the constituent element(s) is/are obviously essential in principle. When numerical values such as the number, amount, dimension, and range of elements are mentioned, the present disclosure is not limited to the specific numerical values unless otherwise specified as essential or obviously limited to the specific numerical values in principle. Similarly, in the case where the shape, the direction, the positional relationship, and/or the like of the constituent element(s) is specified, the present disclosure is not necessarily limited to the shape, the direction, the positional relationship, and/or the like unless the shape, the direction, the positional relationship, and/or the like is/are indicated as essential or is/are obviously essential in principle.

The modifications are also not necessarily limited to the above examples. For example, multiple embodiments may be combined with each other unless technically inconsistent. That is, a part of one embodiment and a part of another embodiment may be combined with each other unless technically inconsistent. Furthermore, any one of the multiple embodiments and any one of the multiple modified examples may be combined with each other unless technically inconsistent. Similarly, one of the multiple modified examples may be combined with another one, unless technically inconsistent.

What is claimed is:

1. A semiconductor device comprising:
a semiconductor substrate for a semiconductor element;
a first electrode provided on one surface of the semiconductor element and formed of an Ni plating layer;
a second electrode provided on the one surface of the semiconductor element and formed of the Ni plating layer; and
a partition wall provided on the one surface of the semiconductor element so as to separate the first electrode and the second electrode from each other, wherein
a phosphorus concentration in the Ni plating layer of the first electrode and the second electrode is 4 wt % or less, and
the partition wall has a convex shape protruding toward the first electrode or the second electrode.

2. The semiconductor device according to claim 1, wherein the semiconductor element is electrically connected to another component via a solder layer, and the solder layer has a melting point of 290° C. or higher.

3. The semiconductor device according to claim 2, wherein the another component is a lead frame and/or a clip fixed to the lead frame.

4. The semiconductor device according to claim 1, wherein
the semiconductor element is formed of the semiconductor substrate having a thickness of 70 μm or less,
the Ni plating layer of the first electrode or the second electrode is formed so that a ratio of a thickness of a columnar crystal layer to a thickness of the Ni plating layer is 50% or less, and
the partition wall is formed so that a radius of curvature of the convex shape is 30 μm or more.

5. The semiconductor device according to claim 1, wherein
the semiconductor element is formed by the semiconductor substrate having a thickness of 160 μm or less,
the Ni plating layer of the first electrode or the second electrode is formed so that a ratio of a thickness of a columnar crystal layer to a thickness of the Ni plating layer is 50% or less, and
the partition wall is formed so that a radius of curvature of the convex shape is 60 μm or more.

6. The semiconductor device according to claim 1, wherein an interlayer interface is formed between the Ni plating layer of the first electrode or the second electrode and the semiconductor substrate, and is flattened so that a step is 0.2 μm or less at least at a position corresponding to the partition wall.

7. The semiconductor device according to claim 1, wherein the partition wall is formed of an insulating film.

8. The semiconductor device according to claim 7, wherein the insulating film is made of a polyimide resin.
